(19) United States
(12) Patent Application Publication
(10) Pub. No.: US 2026/0247833 A1
(43) Pub. Date: Aug. 20, 2026

(54) SUPPORT MEMBER OF DISPLAY APPARATUS AND DISPLAY APPARATUS

(71) Applicant: BOE Technology Group Co., Ltd., Beijing (CN)

(72) Inventors: Lu Liu, Beijing (CN); Haoran Wang, Beijing (CN); Song Zhang, Beijing (CN)

(73) Assignee: BOE Technology Group Co., Ltd., Beijing (CN)

(21) Appl. No.: 18/992,647

(22) PCT Filed: May 22, 2024
(86) PCT No.: PCT/CN2024/094794

§ 371 Date: Jan. 9, 2025

(30) Foreign Application Priority Data
May 31, 2023 (CN) 202310637378.1

(51) Int. Cl. H10K 59/80; H10K 102/00

(52) U.S. Cl. CPC H10K 59/871; H10K 2102/311

(57) ABSTRACT

A support member of a display apparatus and the display apparatus are provided in the embodiments of the present application, the display apparatus includes a plurality of first openings and a plurality of second openings. In a first bending direction, a distance between adjacent first openings is a first distance, and in a second bending direction, a distance between adjacent first openings is a second distance. The first opening includes a first region and a second region. In the first bending direction, a third distance between the first opening and the second opening is greater than twice the first distance. Thus, the first openings can be distributed more rationally to ensure that there may be enough solid reserved among the first openings for support, while a better bending effect can be achieved.

### CROSS-REFERENCES TO RELATED APPLICATIONS

The present application claims the priority of the Chinese patent application filed on May 31, 2023 before the China National Intellectual Property Administration with the application number of 202310637378.1 and the title of “SUPPORT MEMBER OF DISPLAY APPARATUS AND DISPLAY APPARATUS”, which is incorporated herein in its entirety by reference.

### TECHNICAL FIELD

The present application relates to the technical field of display apparatuses and, more particularly, to a support member of a display apparatus and the display apparatus.

### BACKGROUND

With the development of flexible display technology, various applications such as fixed curvature curved screens, foldable screens, wristbands, and rollable screens emerge in endlessly, injecting new vitality into the industrial design of flexible display screens. The outward-bending display module is to bend the display surface of the flexible module outward, and the whole machine is sleek and beautiful. The inward-folding technology is to fold the display module inward. For the convenience of display, the inward bending folding screen may also be equipped with a secondary screen at the outside, which is used for simple display and quickly receiving and making calls. The inward bending technology requires a small bending radius R (1.5 mm-5 mm) in order to reduce a thickness of the module and make the industrial design of the whole machine more beautiful. In order to achieve bidirectional folding, the rigid metal or carbon fiber in the middle need to be completely hollowed out to ensure the realizability of bidirectional bending.

### SUMMARY

A support member of a display apparatus and the display apparatus are provided by the embodiments of the present application.

As an aspect of the embodiment of the present application, a support member of a display apparatus is provided by the embodiments of the present application, the support member of the display apparatus includes:
a plurality of first openings arranged in an array;
a plurality of second openings arranged in an array;
wherein in a first bending direction, a distance between adjacent first openings is a first distance, and in a second bending direction, a distance between adjacent first openings is a second distance;
in the first bending direction, a third distance between the first opening and the second opening that are adjacent is greater than twice the first distance, and in the second bending direction, a fourth distance between the first opening and the second opening that are adjacent is greater than twice the second distance; and
both the first opening and the second opening have a first region and a second region, a midpoint of the first region and a midpoint of the second region are the same, a first width of the first region in the second bending direction is less than a first length of the first region in the first bending direction, and a second width of the second region in the first bending direction is less than a second length of the second region in the second bending direction.

In an embodiment, a value of the first length ranges from twice the first distance to 10 times the first distance.

In an embodiment, a value of the second length ranges from twice the second distance to 10 times the second distance.

In an embodiment, the second length is greater than the first width, and a value of the first width is obtained by subtracting a designated distance from the first distance, wherein the designated distance is less than the first distance.

In an embodiment, a value of the designated distance is taken between one-third of the first distance and four-fifths of the first distance.

In an embodiment, in the second bending direction, there is a first designated solid between the first opening and the second opening, and a line width of the first designated solid ranges from twice the second distance to 10 times the second distance; and
the support member of the display apparatus further includes at least one first half-etched groove, and each of the at least one first half-etched groove is arranged on the first designated solid along the second bending direction.

In an embodiment, a value of an etching depth of the each of the at least one first half-etched groove is taken between one-half of a thickness of the first designated solid and four-fifths of the thickness of the first designated solid.

In an embodiment, in the first bending direction, there is a second designated solid between the first opening and the second opening, and a line width of the second designated solid ranges from twice the first distance to 10 times the first distance; and
the support member of the display apparatus further includes at least one second half-etched groove, and each of the at least one second half-etched groove is arranged on the second designated solid along the second bending direction.

In an embodiment, a value of an etching depth of the each of the at least one second half-etched groove is taken between one-half of a thickness of the second designated solid and four-fifths of the thickness of the second designated solid.

In an embodiment, the first width is the first distance, the first length is 3 times the first distance, and the second length is 3 times the second distance; and in the first bending direction, the third distance is 3 times the first distance, and in the second bending direction, the fourth distance is 3 times the second distance.

In an embodiment, the plurality of the first openings are arranged at equal intervals along the first bending direction and the second bending direction on the support member of the display apparatus.

In an embodiment, the plurality of second openings are arranged at equal intervals along the first bending direction and the second bending direction on the support member of the display apparatus.

In an embodiment, the first region extends along the first bending direction, and the first region is a rectangular through hole arranged along the first bending direction or an elongated through hole arranged along the first bending direction; and

the second region extends along the second bending direction, and the second region is a rectangular through hole arranged along the second bending direction or an elongated through hole arranged along the second bending direction.

In an embodiment, the first opening and the second opening are arranged in a staggered manner.

In an embodiment, an intermediate region of four first openings arranged in an array is configured with one second opening, and centers of the four first openings are connected to form a first rectangle, and a center of the second opening is positioned at a center of the first rectangle; and
an intermediate region of the four second openings arranged in an array is configured with one first opening, and centers of the four second openings are connected to form a second rectangle, and a center of the first opening is positioned at a center of the second rectangle.

In an embodiment, at both sides of the first opening and the second opening along the first bending direction, there are a plurality of third openings arranged in an array, a length of the third opening along the first bending direction is greater than a width of the third opening along the second bending direction.

In an embodiment, a size of the third opening is the same as a size of the first region and a structure of the third opening is the same as the structure of the first region, and the third opening is parallel to the first region.

In an embodiment, a translation center of the first opening is a position obtained by translating a center of the first opening along the first bending direction to align with a center of the second opening in the second bending direction; and
a distance between the translation center of the first opening and the center of the first opening is the third distance, and a distance between the translation center of the first opening and the center of the second opening is the fourth distance.

As another aspect of the embodiment of the present application, the display apparatus is provided by the embodiment of the present application, which includes the support member of the display apparatus according to any one of the specific embodiments stated above.

The above overview is only for the purpose of the instructions and is not intended to be limited in any way. In addition to the schematic aspects, implementation methods and characteristics described above, by referring to the attached figures and the following detailed descriptions, the further aspects, implementation methods and characteristics of this disclosure will be easy to understand.

### BRIEF DESCRIPTION OF THE DRAWINGS

In order to more clearly illustrate the technical solutions of the embodiments of the present application or the related art, the figures that are required to describe the embodiments or the related art may be briefly introduced below. Apparently, the figures that are described below are some embodiments of the present application, and a person skilled in the art can obtain other figures according to these figures without paying creative work.

In the drawings, unless otherwise specified, the same or similar parts or elements are represented by the same figure marks throughout multiple figures. These drawings are not necessarily drawn in proportion. It should be understood that these drawings only describe some embodiments according to the present application, and should not be regarded as a limitation on the scope of the present application.

FIG. 1 shows a schematic structural diagram of a support member of a display apparatus according to an embodiment of the present application;

FIG. 2 shows a schematic diagram of one-dimensional lateral bending structure of a support member of a display apparatus according to an embodiment of the present application;

FIG. 3 shows a schematic diagram of an overall structure of a support member of a display apparatus according to an embodiment of the present application;

FIG. 4 shows a schematic diagram of a partial structure of a support member of a display apparatus according to another embodiment of the present application;

FIG. 5 shows a schematic structural diagram of a support member of a display apparatus according to another embodiment of the present application;

FIG. 6 shows a schematic structural diagram of a support member of a display apparatus according to another embodiment of the present application;

FIG. 7 shows a schematic diagram of a partial structure of a support member of a display apparatus according to another embodiment of the present application; and

FIG. 8 shows a schematic structural diagram of a support member of a display apparatus according to another embodiment of the present application.

### DETAILED DESCRIPTION

In the following, only certain exemplary embodiments are described briefly. As those skilled in the art will recognize, the described embodiments can be modified in various ways without departing from the spirit or scope of the present application. Therefore, the drawings and descriptions are considered to be essentially exemplary rather than restrictive.

With the development of flexible display technology, various applications such as fixed curvature curved screens, foldable screens, wristbands, and rollable screens emerge in endlessly, injecting new vitality into the industrial design (ID) of the flexible display screens. The outward-bending display module is to bend the display surface of the flexible module outward, and the whole machine is sleek and beautiful. The inward-folding technology is to fold the display module inward. For the convenience of display, the inward bending folding screen may also be equipped with a secondary screen at the outside, which is used for simple display and quickly receiving and making calls. The inward bending technology requires a small bending radius R (1.5 mm-5 mm) in order to reduce a thickness of the module and make the ID of the whole machine more beautiful.

At the same time, in terms of application form, it is also from small and medium-sized mobile phones or tablets (5 inches-8 inches) to more than ten inches of notebook size (about 17 inches when unfolded, about 11 inches when folded). At present, there are inward-folding notebook products on the market. Due to the various sizes of the notebook and the obvious boundary effect, the bending strain of large-size flexible organic light-emitting diode (OLED) screen is large, so the folding radius R of current notebook-sized OLED screen is generally 3 mm-5 mm.

In order to expand the application form of folded notebooks, a notebook with an application form that can be folded in two directions is designed. In one direction, the notebook is symmetrically folded (easy to store), and in the other direction, the notebook is bent in an asymmetrical proportion, thus both large-screen display and human-machine interface interaction can be taken into account.

The forms of the flexible OLED screens, such as folding, sliding or rolling, involve one-dimensional deformation, that is, the flexible OLED screen deforms in only one direction while maintaining its shape in the other horizontal direction, and the stronger the rigidity, the better. In order to enhance strength and support for different bending directions, and increase the connection performance to the whole machine at the same time, a steel plate or carbon fiber sheet with a certain thickness (such as 0.1 mm-0.3 mm steel plate or carbon fiber sheet) is generally used, which is achieved by punching an elongated hole in a single direction.

However, this method is not suitable for a bidirectional folding OLED area bent in two dimensions. In order to achieve bidirectional folding, the rigid metal or carbon fiber in the intermediate region should be completely hollowed out to ensure the realizability of the bidirectional bending. However, the support of this region is quite poor due to the gap (0.1 mm-0.3 mm) with a thickness of a support member between the bidirectional bending area and the whole machine, this gap may lead to a problem such as a collapsing feel in the front display module mold printing and the touch.

Additionally, it may also be considered to fill the hollowed-out areas with bendable materials such as foam, polyimide (PI), or polyethylene terephthalate (PET). However, due to the influence of fitting precision and material processing accuracy, the filling materials need to leave a certain gap with the surrounding support members, this gap may lead to the generation of a front ring-shaped mold printing of the display apparatus. Furthermore, the support of the low-modulus bendable materials is poor, which may result in a different tactile feel compared to other areas.

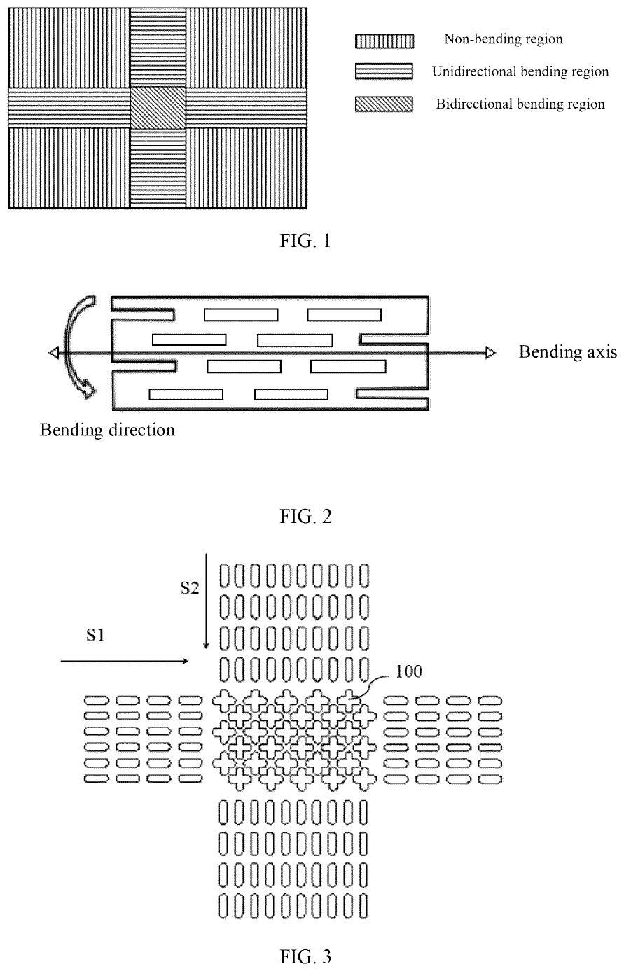

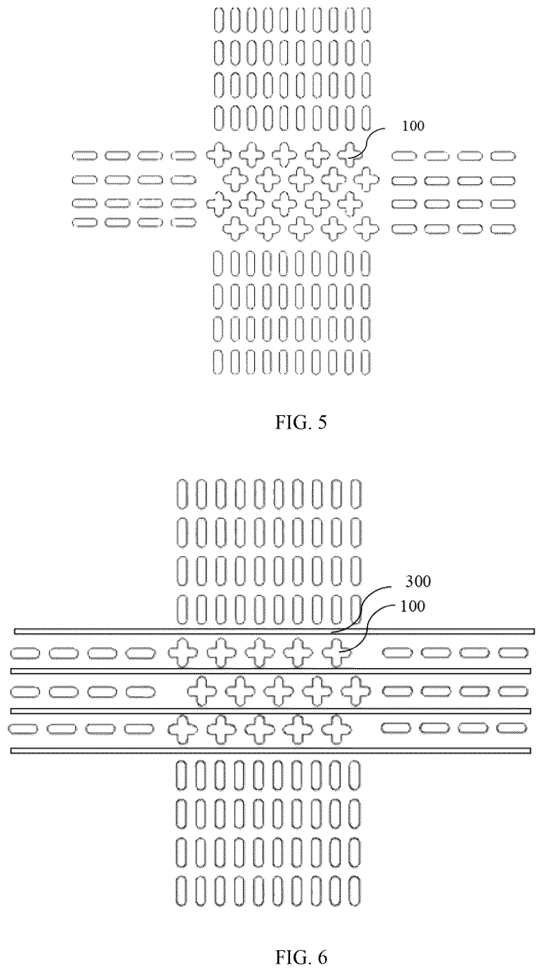

As shown in FIGS. 1 to 5, FIG. 1 shows a schematic structural diagram of a support member of a display apparatus according to an embodiment of the present application. A support member of a display apparatus is provided by a first aspect of the present application, the support member of the display apparatus includes:
a plurality of first openings 100 arranged in an array;
a plurality of second openings 400 arranged in an array;
the first opening 100 have a first region 110 and a second region 120, a midpoint of the first region 110 and a midpoint of the second region 120 are the same, a first width D of the first region 110 in the second bending direction S2 is less than a first length C of the first region 110 in the first bending direction S1, and a second width F of the second region 120 in the first bending direction S1 is less than a second length E of the second region 120 in the second bending direction S2;
in the first bending direction S1, a minimum distance between adjacent first openings 100 is a first distance A, and in a second bending direction S2, a minimum distance between adjacent first openings is a second distance B; and
in the first bending direction S1, a third distance G between the first opening 100 and the second opening 400 that are adjacent is greater than twice the first distance A, and in the second bending direction S2, a fourth distance H between the first opening 100 and the second opening 400 that are adjacent is greater than twice the second distance.

The display apparatus in the present embodiment can be a flexible display screen, as shown in FIGS. 1, 2 and 3, in the unidirectional bending area, a conventional unidirectional arranged opening method can be used, lateral bending refers to bending along the first bending direction S1, and the arranged openings are lateral arranged openings, i.e., the first region 110; longitudinal bending refers to bending along the second bending direction S2, and the arranged openings are longitudinal arranged openings, i.e., the second region 120. Taking lateral bending as an example, a schematic diagram of the bending is shown in FIG. 2. The first bending direction S1 can also be defined as the X-axis direction, which can usually be the length direction of the display apparatus. The second bending direction S2 can also be defined as the Y-axis direction, which can usually be the width direction of the display apparatus. Of course, the first bending direction S1 and the second bending direction S2 can also be adjusted, and the first bending direction S1 and the second bending direction S2 can usually be perpendicular to each other. It should be noted that in the present embodiment, the first bending direction S1 is the length direction of the display apparatus, and the second bending direction S2 is the width direction of the display apparatus. For other configurations of the first bending direction S1 and the second bending direction S2, adjustments can be made according to actual conditions.

As shown in FIG. 3, in the present embodiment, that the plurality of first openings 100 are arranged in an array can specifically be: the plurality of first openings 100 are arranged at equal intervals along the first bending direction S1 and the second bending direction S2 on the support member of the display apparatus. That the plurality of second openings 400 are arranged in an array can specifically be: the plurality of second openings 400 are arranged at equal intervals along the first bending direction S1 and the second bending direction S2 on the support member of the display apparatus. Both the first opening 100 and the second opening 400 have a first region 110 and a second region 120. The first region 110 extends along the first bending direction S1, and since the first length C of the first region 110 is greater than the first width D, the first region 110 can be configured as a rectangular through hole arranged laterally, or the first region 110 can also be a non-standard rectangle, or similar to a through hole similar to an elongated through hole, etc., as long as it is satisfied that the first length C is greater than the first width D. The second region 120 extends along the second bending direction S2, and since the second length E of the second region 120 is greater than the second width F, the second region 120 can be configured as a rectangular through hole arranged longitudinally, or the second region 120 can be a non-standard rectangle, or a through hole similar to an elongated through hole, etc., as long as it is satisfied that the second length E is greater than the second width F. The shape of the first region 110 can be the same as the shape of the second region 120, that is, the first length C is equal to the second length E, and the first width D is equal to the second width F. The size of the first region 110 can be the same as or different from the size of the second region 120. The midpoint of the first region 110 and the midpoint of the second region 120 are the same, so that the first region 110 and the second region 120 form a shape resembling a “cross”, such as a cross-shaped interlocking arrangement pattern. By using the arrangement of the first openings 100, the support member of the display apparatus can be bent in both the first bending direction S1 and the second bending direction S2, the object of bending in two directions is achieved to meet the requirements for the display apparatus to perform bidirectional bending.

As shown in FIG. 3, the first opening and the second opening 400 are arranged in a staggered manner, that is, an intermediate region of the four first openings arranged in an array can be configured with one second opening 400; centers of the four first openings are connected to form a rectangle, and a center of the second opening 400 can be positioned at a center of the rectangle. At the same time, an intermediate region of the four second openings 400 arranged in an array can be configured with one first opening, centers of the four second openings 400 are connected to form another rectangle, and a center of the first opening can be positioned at a center of the another rectangle. By using this method, the first opening and the second opening 400 can be disposed in a staggered manner.

At both sides of the first opening and the second opening 400 along the first bending direction, there are a plurality of third openings arranged in an array, a length of the third opening along the first bending direction is greater than a width of the third opening along the second bending direction. A size of the third opening may be the same as a size of the first region and a structure of the third opening may be the same as the structure of the first region, and at the same time, for the position, the third opening and the first region may be parallel to each other. For example, there can be three first openings and three third openings arranged along the second bending direction, that is, there are six first regions along the second bending direction, with each first region corresponding to a third opening. That is, there may also be six third openings, with each first region aligned with its corresponding third opening, and the sizes and structures of the first regions and the third openings can also be the same. In the first bending direction, the quantity of the first openings can be five or another quantity, the quantity of the second openings 400 can also be five or another quantity. The quantity of the third openings along the first bending direction can be four or any other quantity. By using the third openings, the solid area in the first bending direction can be reduced, so that the bendability in the first bending direction can be enhanced.

At both sides of the first opening and the second opening 400 along the second bending direction, there are a plurality of fourth openings arranged in an array, a length of the fourth opening along the second bending direction is greater than a width of the fourth opening along the first bending direction. A size of the fourth opening may be the same as a size of the second region and a structure of the fourth opening may be the same as the structure of the second region, and at the same time, for the position, the fourth opening and the second region may be parallel to each other. For example, there can be five first openings and five third openings arranged along the first bending direction, that is, there are ten first regions along the first bending direction, with each second region corresponding to one fourth opening. That is, there may also be ten fourth openings, with each second region aligned with its corresponding fourth opening, and the sizes and structures of the second regions and the fourth openings can also be the same. In the second bending direction, the quantity of the first openings can be three or another quantity, the quantity of the second openings 400 can also be three or another quantity. The quantity of the fourth openings along the second bending direction can be four or any other quantity. By using the fourth openings, the solid area in the second bending direction can be reduced, so that bendability in the second bending direction is enhanced.

By using the aforementioned first opening 100 having the first region 110 and the second region 120, the purpose of bidirectional bending can be achieved. At the same time, in the present embodiment, the openings on the support member can be classified into the first opening 100 and the second opening 400 according to their arrangement modes. The arrangement mode of the first openings 100 and the arrangement mode of the second openings 400 are the same, both the first openings 100 and the second openings 400 are arranged in an array. The shapes and structures of the first openings 100 and the second openings 400 are also the same. In the first openings 100 and the second openings 400, the minimum distance between adjacent first openings 100 in the first bending direction S1 is the first distance A, the minimum distance between adjacent first openings in the second bending direction S2 is the second distance B. Specifically, the minimum distance between the first regions of two adjacent first openings is the first distance A, that is, the minimum distance between the two first regions disposed opposite to each other of the two adjacent first openings along the first bending direction is the first distance A. The minimum distance between the second regions of two adjacent first openings is the second distance B, that is, the minimum distance between the two second regions disposed opposite to each other of two adjacent first openings along the second bending direction is the second distance B. The positions represented by the first distance A and the second distance B are the range of solid, that is, by maintaining the first distance A and the second distance B, the first opening 100 can have sufficient solid to provide support. Thus, it is ensured that the support member can achieve bending while having adequate support, so that the problem of poor support caused by excessive hollowing of the support member to lead to a problem such as a collapsing feel in the front display module mold printing and the touch can be avoided.

In the present embodiment, the design of the support member varies according to the model and size of the display apparatus. The size of the first distance A and the size of the second distance B can be determined based on the actual size and model of the display apparatus. The first distance A can be the same as or different from the second distance B.

In the present embodiment, in the first bending direction S1, the third distance G between the first opening 100 and the second opening 400 that are adjacent is greater than twice the first distance A, that is, greater than 2A. In the second bending direction S2, the fourth distance H between the first opening 100 and the second opening 400 that are adjacent is greater than twice the second distance B, that is, greater than 2B. In this way, a staggered configuration of the openings can be achieved, so that a larger area can be hollowed out to form openings to enhance the bending effect of the support member, at the same time, the solid having sufficient support portion can be retained to ensure that the support member can play a good role in supporting.

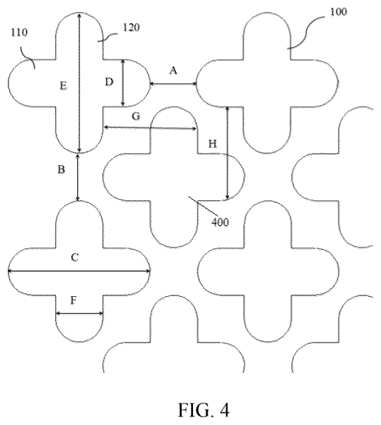

As shown in FIG. 4, in some specific embodiments, in the first bending direction S1, the third distance G between the first opening 100 and the second opening 400 that are adjacent can be twice the first distance A (that is, 2A), three times the first distance A (that is, 3A), or four times the first distance A (that is, 4A), and so on, which can be set according to the actual situations. Similarly, in some specific embodiments, in the second bending direction S2, the fourth distance H between the first opening 100 and the second opening 400 that are adjacent can be twice the second distance B (that is, 2B), three times the second distance B (that is, 3B), or four times the second distance B (that is, 4B), and so on, which can also be set according to the actual situations.

As shown in FIG. 4, a translation center of the first opening is a position obtained by translating a center of the first opening along the first bending direction to align with a center of the second opening in the second bending direction; and a distance between the translation center of the first opening and the center of the first opening is the third distance G, and a distance between the translation center of the first opening and the center of the second opening 400 is the fourth distance H. Alternatively, in the first bending direction, the distance between the edge at one side of the second region of the first opening and the edge at the corresponding side of the second region of the second opening 400 closest to the first opening is the third distance G. For example, the distance between the right edge of the second region of the first opening and the corresponding right edge of the second region of the second opening 400 closest to the first opening is the third distance G. In the second bending direction, the distance between the edge at one side of the first region of the first opening and the edge at the corresponding side of the first region of the second opening 400 closest to the first opening is the fourth distance H. For example, the distance between the lower edge of the first region of the first opening and the corresponding lower edge of the first region of the second opening 400 closest to the first opening is the fourth distance H.

In the present embodiment, a plurality of first openings 100 are arranged along the first bending direction S1 and the second bending direction S2. Each first opening 100 has a first region 110 and a second region 120, the midpoint of the first region 110 and the midpoint of the second region 120 are the same. In the first region 110, the first width D is less than the first length C. In the second region 120, the second width F is less than the second length E, enabling the display apparatus to bend along both the first bending direction S1 and the second bending direction S2 to achieve the bidirectional bending purposes. The openings on the support member can be classified based on their arrangement into the first openings 100 and the second openings 400. In the first bending direction S1, the distance between adjacent first openings 100 is the first distance A, and the third distance G between the first opening 100 and the second opening 400 that are adjacent in the first bending direction S1 is greater than twice the first distance A. In the second bending direction S2, the distance between adjacent first openings is the second distance B, and the fourth distance H between the first opening 100 and the second opening 400 that are adjacent in the second bending direction S2 is greater than twice the second distance B. Thus, the openings can be reasonably distributed to ensure that sufficient solid are reserved among the openings for support, while good bending effects can also be achieved. This effectively avoids the need to completely hollow out the intermediate rigid metal or carbon fiber to ensure the realizability of bidirectional bending, avoids that poor support in the hollowed-out regions is lead to and avoids that a problem such as a collapsing feel in the front display module mold printing of the display apparatus and the touch is resulted in.

At the same time, there is no need for extra filling with bendable materials, such as foam, PI, or PET, thus that the gap needed between the filling material and the surrounding support member due to the effect of fitting precision and material processing accuracy may lead to the problem of generating the front ring mold printing of the display apparatus is avoided. Thus, while the support effectiveness of the support member can be ensured, the problem of touch feeling in other areas may not exist.

In an embodiment, a value of the first length C ranges from twice the first distance A to 10 times the first distance A.

The first length C along the first bending direction S1 should not be too large. If the first length C is too large, it may result in a larger hollowed-out area range, leading to poor support of the support member and leading to a problem of collapse on the front of the display apparatus and the touch. Furthermore, if the first length C is too large, the rigidity of the support member of the display apparatus is poor, and the risk of breakage happens easily.

In the present embodiment, by relating the first length C of a certain first opening 100 to the first distance A between the first opening 100 and its adjacent first opening 100, the first length C is limited to a range of 2 times the first distance A to 10 times the first distance A, that is, the range of the first length C may be 2A to 10A. Therefore, the first length C can be limited within an appropriate range, that is, sufficient hollowed-out area for the support member can be ensured, while adequate solid range can also be ensured. This can effectively avoid the need to completely hollow out the intermediate rigid metal or carbon fiber to ensure the realizability of bidirectional bending, avoid that poor support in the hollowed-out regions is lead to and avoid that a problem such as a collapsing feel in the front mold printing of the display apparatus and the touch is resulted in.

In the present embodiment, the first length C may be three times the first distance A, i.e., 3A. Certainly, the first length C may also be 3.5 times the first distance A, i.e., 3.5A. The first length C may also be 4 times the first distance A, i.e., 4A. The first length C may also be 5 times the first distance A, i.e., 5A. The first length C may be selected in other suitable manner.

In the present application, by associating the first length C with the first distance A, in the first bending direction S1, it is ensured that the scope of the solid can be associated with the scope of the hollowed-out first region 110. There is no problem of poor support due to the excessive hollowing range, at the same time, the bending performance in the first bending direction S1 can be better taken into account.

In another embodiment, a value of the second length E ranges from twice the second distance B to 10 times the second distance B.

Along the second bending direction S2, the second length E should also not be too large. If the second length E is too large, it may result in a larger hollowed-out area range, leading to poor support of the support member and leading to a problem of collapse on the front of the display apparatus and the touch. Furthermore, if the second length E is too large, the rigidity of the support member of the display apparatus is poor, and the risk of breakage happens easily.

In the present embodiment, by relating the second length E of a certain first opening 100 to the second distance B between the first opening 100 and its adjacent first opening 100, the second length E is limited to a range of 2 times the second distance B to 10 times the second distance B, that is, the range of the second length E may be 2B to 10B. Therefore, the second length E can be limited within an appropriate range, that is, sufficient hollowed-out area for the support member can be ensured, while adequate solid range can also be ensured. This can effectively avoid the need to completely hollow out the intermediate rigid metal or carbon fiber to ensure the realizability of bidirectional bending, avoid that poor support in the hollowed-out regions is lead to and avoid that a problem such as a collapsing feel in the front mold printing of the display apparatus and the touch is resulted in.

In the present embodiment, the second length E may be three times the second distance B, i.e., 3B. Certainly, the second length E may also be 3.5 times the second distance B, i.e., 3.5B. The second length E may also be 4 times the second distance B, i.e., 4B. The second length E may also be 5 times the second distance B, i.e., 5B. The second length E may be selected in other suitable manner.

In the present application, by associating the second length E with the second distance B, in the second bending direction S2, it is ensured that the scope of the solid can be associated with the length scope of the hollowed-out second region 120. There is no problem of poor support due to the excessive hollowing range, at the same time, the bending performance in the second bending direction S2 can be better taken into account.

In the present embodiment, a value of the first width D is obtained by subtracting a designated distance from the first distance A, wherein the designated distance is less than the first distance A.

The radius of lateral bending and the radius of longitudinal bending are not necessarily the same. For example, the bending in the second bending direction S2 (i.e., the Y direction) can be small radius bending (a bending radius R is 1 mm to 3 mm), while the bending in the first bending direction S1 (i.e., the X direction) can be relatively large radius bending (a bending radius R is 5 mm).

In the present embodiment, by adjusting the first width D of the first region 110, the first width D of the first region 110 can be further reduced to be less than the first distance A, that is, the value of the first width D is obtained by subtracting a designated distance n from the first distance A (i.e., A-n). The designated distance n is less than the first distance A, so that there is a larger solid range on the support member, the support solid of the support member in the first bending direction S1 is more, while the support solid in the second bending direction S2 is unchanged. Thus, it is realized that the bending in the second bending direction S2 (i.e., the Y direction) is small radius bending (a bending radius R is 1 mm to 3 mm) and the bending in the first bending direction S1 (i.e., the X direction) is relatively large radius bending (a bending radius R is 5 mm). In this way, it may be ensured that the bending in the second bending direction S2 is not affected, the bending radius in the first bending direction S1 is larger and high flexibility is not required to adapt to usage requirements for different display apparatuses.

Similarly, when the bending in the first bending direction S1 (i.e., the X direction) is small radius bending (a bending radius R is 1 mm to 3 mm) and the bending in the second bending direction S2 (i.e., the Y direction) is relatively large radius bending (a bending radius R is 5 mm), by adjusting the second width F of the second region 120, the second width F of the second region 120 can be further reduced to be less than the second distance B, that is, a value of the second width F is obtained by subtracting a designated distance n from the second distance B (i.e., B−n). The designated distance n is less than the second distance B, so that there is a larger solid range on the support member, the support solid of the support member in the second bending direction S2 is more, while the support solid in the first bending direction S1 is unchanged. Thus, it is realized that the bending in the first bending direction S1 (i.e., the X direction) is small radius bending (a bending radius R is 1 mm to 3 mm) and the bending in the second bending direction S2 (i.e., the Y direction) is relatively large radius bending (a bending radius R is 5 mm). In this way, it may be ensured that the bending in the first bending direction S1 is not affected, the bending radius in the second bending direction S2 is larger and high flexibility is not required.

In some embodiments, by increasing the first distance A of the first opening 100 and the second opening 400 along the first bending direction S1, for example, increasing to be twice the first distance A, i.e., 2A, or 3 times the first distance A, i.e., 3A, or adding a designated distance n to the original distance (i.e., A+n), the support solid of the support member in the first bending direction S1 is more, while the support solid in the second bending direction S2 remain unchanged, thus it is realized that the bending in the second bending direction S2 (i.e., the Y-direction) is a small radius bending (a bending radius R is 1 mm to 3 mm), and the bending in the first bending direction S1 (i.e., the X-direction) is a relatively larger radius bending (a bending radius R is 5 mm) to adapt to usage requirements for different display apparatuses. It is ensured that the bending in the second bending direction S2 is unaffected, the bending radius in the first bending direction S1 is larger and high flexibility is not required.

In situations where the bending radii in the two directions differ, leaving as much solid area as possible can further enhance support.

As shown in the table below:

| Pattern | Solid Area | Support | Bending Performance |
|---|---|---|---|
| Completely Hollow | 0 | Poor | Good |
| Partially Hollow | 15%-50% | Moderate | Good |
| Fully Metal Solid | 100% | Good | Poor |

From the above table, it can be known that for the support member, the larger the hollowed-out solid area, the worse the support and the better the bending performance. Conversely, the smaller the hollowed-out solid area, the better the support, but the worse the bending performance.

In some embodiments, by increasing the second distance B of the adjacent first openings 100 along the second bending direction $2, for example, increasing to be twice the second distance B, i.e., 2B, or 3 times the second distance B, i.e., 3B, or adding a designated distance n to the original distance (i.e., B+n), the solid range of the support member is more, so that the support solid of the support member in the second bending direction S2 is more, while the support solid in the first bending direction S1 remain unchanged, thus it is realized that the bending in the first bending direction S1 (i.e., the X-direction) is a small radius bending (a bending radius R is 1 mm to 3 mm), and the bending in the second bending direction S2 (i.e., the Y-direction) is a relatively larger radius bending (a bending radius R is 5 mm).

In one embodiment, the second length is greater than the first width, and a value of the designated distance is taken between one-third of the first distance A and four-fifths of the first distance A.

In the present embodiment, the first width of the first region along the second bending direction is less than the first length of the first region along the first bending direction, which can ensure that the first opening can form a cross pattern.

For the designated distance n, it can be selected according to practical conditions, however, in order to avoid the first region 110 being too small, at the same time, it can be realized that the bending in the second bending direction S2 (i.e., Y direction) can be small radius bending (a bending radius R is Imm to 3 mm) and the bending in the first bending direction S1 (i.e. the X direction) is relatively large radius bending (a bending radius R is 5 mm), a value of the designated distance can be taken between one-third of the first distance A and four-fifths of the first distance A, that is, n ranges from (⅓) A to (⅘) A. That is, the designated distance can be specifically one-third of the first distance A, that is, (⅓) A. By limiting the designated distance, when the first width D is adjusted, the adjustment range can be better controlled, and the problem that the first region 110 is adjusted too small may not occur.

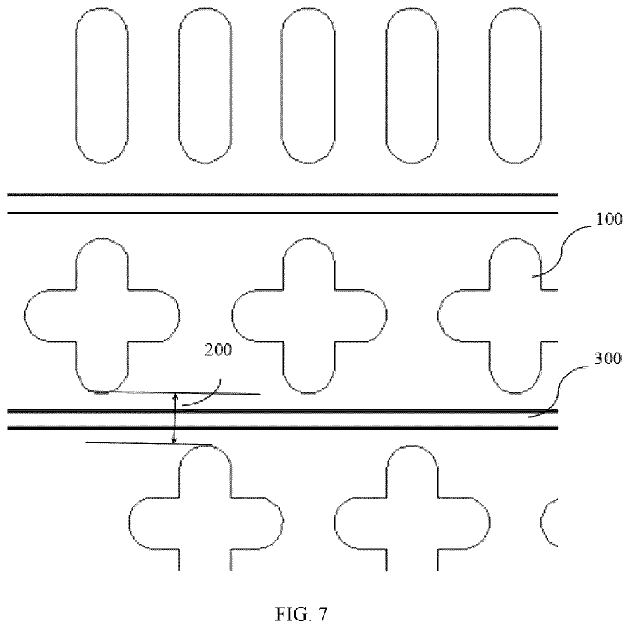

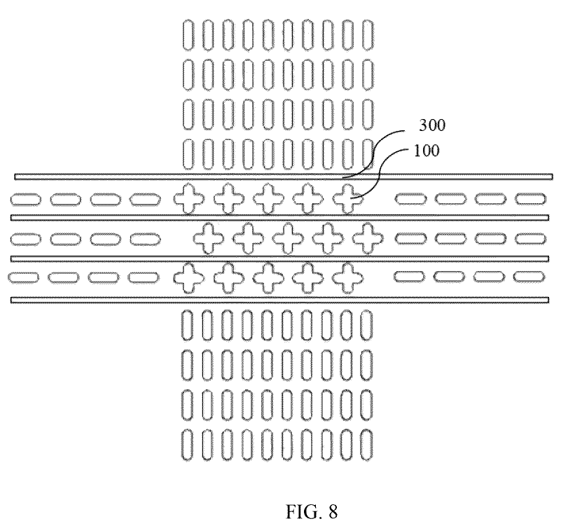

As shown in FIGS. 6 to 8, in an embodiment, in the second bending direction S2, there is a first designated solid 200 between the first opening 100 and the second opening 400, and a line width of the first designated solid 200 ranges from twice the second distance B to 10 times the second distance B.

There is a first designated solid 200 between the first opening 100 and the second opening 400. Specifically, the solid between the lowest point of the first opening 100 along the second bending direction S2 and the highest point of the second opening 400 along the second bending direction S2 is the first designated solid 200. In some embodiments, the width of the first designated solid 200 along the second bending direction S2 can be 0. For example, as shown in FIG. 4, if the position of the lowest point of the first opening 100 along the second bending direction S2 is lower than the position of the highest point of the second opening 400 along the second bending direction S2, there is no first designated solid 200 between the first opening 100 and the second opening 400. In the present embodiment, as shown in FIGS. 6 to 8, the width of the first designated solid 200 along the second bending direction S2 is a positive number, which is twice the second distance B to 10 times the second distance B, i.e., 2B to 10B. For a U-shaped bending in the X direction with a radius of 5 mm, the ratio of the line width of the first designated solid 200 to the second distance B is 10:1, and the bending can still be completed.

In an embodiment, the support member of the display apparatus further includes:
at least one first half-etched groove 300, and each of the at least one first half-etched groove 300 is arranged on the first designated solid 200 along the second bending direction S2.

For situations where the bending radii in the two directions differ, leaving as much solid area as possible, the ratio of the line width of the first designated solid 200 to the second distance B can be increased to be 2-10:1, that is, the line width of the first designated solid 200 ranges from 2 second distance B to 10 second distance B. In order to ensure better bending performance of the first bending direction S1, some first half-etched grooves 300 can be made in the first designated solid 200 area to form a half-etched area and increase the bending capability in the first bending direction S1.

In particular, when the ratio of the line width of the first designated solid 200 to the second distance B is 10:1, by adding multiple etched grooves, the bending capability in the first bending direction S1 can be effectively enhanced, so as to ensure that when sufficient support strength is met, bending performance can be met at the same time, various different requirements on the display apparatus can be met.

In another example, when the bending radius in the first bending direction S1 is larger, high flexibility is not required. For a U-shaped bending with a radius of 5 mm in the first bending direction S1, the ratio of the line width of the first designated solid 200 to the second distance B is 3:1. However, in the area of the first designated solid 200 area, semi-etching can be performed, the semi-etching can be one or multiple grooves. The first half-etched groove 300 can be a single groove or multiple parallel grooves or several segments of first half-etched grooves 300. By using the first half-etched groove 300, the rigidity at the first designated solid 200 can be reduced, thereby part of the support capability can be reduced, while the bending capability of the portion of the first designated solid 200 is enhanced.

In the present embodiment, there are no special restrictions on the depth of the semi-etching; which can be freely designed according to the bending radius and the required bending degree.

In an embodiment, a value of an etching depth of the each of the at least one first half-etched groove 300 is taken between one-half of a thickness of the first designated solid 200 and four-fifths of the thickness of the first designated solid 200.

For the etching depth of the first half-etched groove 300, if the etching depth of the first half-etched groove 300 is too small, the bending capability cannot be effectively enhanced.

Therefore, in the present embodiment, a value of an etching depth of the first half-etched groove 300 is taken between one-half of a thickness of the first designated solid 200 and four-fifths of the thickness of the first designated solid 200. Specifically, a value of the etching depth of the first half-etched groove 300 is taken between one-half of the substrate thickness of the first designated solid 200 and four-fifths of the substrate thickness of the first designated solid 200. By setting that a value of the etching depth of the first half-etched groove 300 is taken between one-half of the thickness of the first designated solid 200 and four-fifths of the thickness of the first designated solid 200, it can be ensured that the first half-etched groove 300 corresponding to the first designated solid 200 is hollowed out, thereby the bending performance of the first designated solid 200 is improved without causing significant damage to its supporting performance, so as to make the support member to take the bending performance and the supporting performance into account.

In an embodiment, in the first bending direction, there is a second designated solid between the first opening and the second opening 400, and a line width of the second designated solid ranges from twice the first distance to 10 times the first distance; and

the support member of the display apparatus further includes at least one second half-etched groove, and each of the at least one second half-etched groove is arranged on the second designated solid along the second bending direction.

There is a second designated solid between the first opening 100 and the second opening 400. Specifically, the solid between the lowest point of the first opening 100 along the second bending direction S1 and the highest point of the second opening 400 along the first bending direction S1 is the second designated solid. In some embodiments, the width of the second designated solid along the first bending direction S1 can be 0. In the present embodiment, the width of the second designated solid along the first bending direction S1 is a positive number, which is twice the first distance A to 10 times the first distance A, i.e., 2A to 10A. For a U-shaped bending in the X direction with a radius of 5 mm, the ratio of the line width of the second designated solid to the first distance A is 10:1, and the bending can still be completed.

In an embodiment, the support member of the display apparatus also includes:
at least one second half-etched groove, and each of the at least one second half-etched groove is arranged on the second designated solid along the second bending direction S2.

For situations where the bending radii in the two directions differ, leaving as much solid area as possible, the ratio of the line width of the second designated solid to the first distance A can be increased to be 2-10:1, that is, the line width of the second designated solid ranges from 2 first distance A to 10 first distance A. In order to ensure better bending performance of the second bending direction S2, some second half-etched grooves can be made in the second designated solid area to form a half-etched area and increase the bending capability in the second bending direction S2.

In particular, when the ratio of the line width of the second designated solid to the first distance A is 10:1, by adding multiple etched grooves, the bending capability in the second bending direction S2 can be effectively enhanced, so as to ensure that when sufficient support strength is met, bending performance can be met at the same time, various different requirements on the display apparatus can be met.

In another example, when the bending radius in the second bending direction S2 is larger, high flexibility is not required. For a U-shaped bending with a radius of 5 mm in the second bending direction S2, the ratio of the line width of the second designated solid to the first distance A is 3:1. However, in the area of the second designated solid area, semi-etching can be performed, the semi-etching can be one or multiple grooves. The second half-etched groove can be a single groove or multiple parallel grooves or several segments of second half-etched grooves. By using the second half-etched groove, the rigidity at the second designated solid can be reduced, thereby part of the support capability can be reduced, while the bending capability of the portion of the second designated solid is enhanced.

In the present embodiment, there are no specific restrictions on the depth of the semi-etching, which can be freely designed according to the bending radius and the required bending degree.

In one embodiment, a value of an etching depth of the second half-etched groove is taken between one-half of a thickness of the second designated solid and four-fifths of the thickness of the second designated solid.

For the etching depth of the second half-etched groove, if the etching depth of the second half-etched groove is too small, the bending capability cannot be effectively enhanced.

Therefore, in the present embodiment, a value of an etching depth of the second half-etched groove is taken between one-half of a thickness of the second designated solid and four-fifths of the thickness of the second designated solid. Specifically, a value of the etching depth of the second half-etched groove is taken between one-half of the substrate thickness of the second designated solid and four-fifths of the substrate thickness of the second designated solid. By setting that a value of the etching depth of the second half-etched groove is taken between one-half of the thickness of the second designated solid and four-fifths of the thickness of the second designated solid, it can be ensured that the second half-etched groove corresponding to the second designated solid is hollowed out, thereby the bending performance of the second designated solid is improved without causing significant damage to its supporting performance, so as to make the support member to take the bending performance and the supporting performance into account.

In an embodiment, the first width D is the first distance A, the first length C is three times the first distance A, and the second length E is three times the second distance B. In the first bending direction S1, the third distance G between the first opening 100 and the second opening 400 is three times the first distance A. In the second bending direction S2, the fourth distance H between the first opening 100 and the second opening 400 is three times the second distance B.

In the present embodiment, for the first region 110, the first width D of the first region 110 formed along the second bending direction S2 is the first distance A, and the first length C of the first region 110 formed along the first bending direction S1 is three times the first distance A, thus the structure of the first region 110 is formed, the first region 110 can be rectangular, similar to a rectangle, or other similar shapes.

For the second region 120, the second width F of the second region 120 formed along the first bending direction S1 is the second distance B, and the second length E of the second region 120 formed along the second bending direction S2 is three times the second distance B, thus the structure of the second region 120 is formed, the second region 120 can be rectangular, similar to a rectangle, or other similar shapes. The first bending direction S1 and the second bending direction S2 are perpendicular to each other, with the center of the first region 110 and the center of the second region 120 being the same, thereby a hollow pattern resembling a cross shape can be achieved to reduce the rigidity of the support member and enhance the bending performance of the support member.

As another aspect of the embodiments of the present application, a display apparatus is provided by the embodiment of the present application, which includes the support member of the display apparatus according to any one of the above specific embodiments.

The display apparatus of the present embodiment may be a flexible display screen. In the unidirectional bending area, a conventional unidirectional arranged opening method can be used, lateral bending refers to bending along the first bending direction S1, and the arranged openings are lateral i.e., the first region 110; longitudinal bending refers to bending along the second bending direction S2, and the arranged openings are longitudinal, i.e., the second region 120. Taking lateral bending as an example, a schematic diagram of the bending is shown in FIG. 2. The first bending direction S1 may be the first bending direction and may also be defined as the X-axis direction, which can usually be the length direction of the display apparatus. The second bending direction S2 may be the second bending direction and may also be defined as the Y-axis direction, which can usually be the width direction of the display apparatus. Of course, the first bending direction S1 and the second bending direction S2 can also be adjusted, and the first bending direction S1 and the second bending direction S2 can usually be perpendicular to each other. For convenience, it is first illustrated that in the present embodiment, the first bending direction S1 is the length direction of the display apparatus, and the second bending direction S2 is the width direction of the display apparatus. For other configurations of the first bending direction S1 and the second bending direction S2, adjustments can be made according to actual conditions.

In the present embodiment, the plurality of first openings 100 are arranged at equal intervals along the first bending direction S1 and the second bending direction S2 on the support member of the display apparatus. The first opening 100 have a first region 110 and a second region 120. The first region 110 extends along the first bending direction S1, and since the first length C of the first region 110 is greater than the first width D, the first region 110 can be configured as a rectangular through hole arranged laterally, or the first region 110 can also be a non-standard rectangle, or similar to an elongated through hole, etc., as long as it is satisfied that the first length C is greater than the first width D. The second region 120 extends along the second bending direction S2, and since the second length E of the second region 120 is greater than the second width F, the second region 120 can be configured as a rectangular through hole arranged longitudinally, or the second region 120 can be a non-standard rectangle, or a through hole similar to an elongated through hole, etc., as long as it is satisfied that the second length E is greater than the second width F. The shape of the first region 110 can be the same as the shape of the second region 120, that is, the first length C is equal to the second length E, and the first width D is equal to the second width F. The size of the first region 110 can be the same as or different from the size of the second region 120. The midpoint of the first region 110 and the midpoint of the second region 120 are the same, so that the first region 110 and the second region 120 form a shape resembling a “cross”. Through the arrangement of the first openings 100, the support member of the display apparatus can be bent in both the first bending direction S1 and the second bending direction S2, the goal of bending in two directions is achieved to meet the requirements for the display apparatus to perform bidirectional bending.

By using the aforementioned first opening 100 having the first region 110 and the second region 120, the purpose of bidirectional bending can be achieved. At the same time, in the present embodiment, the openings on the support member can be classified into the first opening 100 and the second opening 400 according to their arrangement modes. The arrangement mode of the first openings 100 and the arrangement mode of the second openings 400 are the same, both the first openings 100 and the second openings 400 are arranged in an array. The shapes and structures of the first openings 100 and the second openings 400 are also the same. In the first openings 100 and the second openings 400, the distance between adjacent first openings 100 in the first bending direction S1 is the first distance A, the distance between adjacent first openings in the second bending direction S2 is the second distance B. The positions represented by the first distance A and the second distance B are the range of solid, that is, by maintaining the first distance A and the second distance B, the first opening 100 can have sufficient solid to provide support. Thus, it is ensured that the support member can achieve bending while having adequate support, so that poor support caused by excessive hollowing of the support member results in a problem such as a collapsing feel in the front display module mold printing and the touch can be avoided.

In the present embodiment, the design of the support member varies according to the model and size of the display apparatus. The size of the first distance A and the size of the second distance B can be determined based on the actual size and model of the display apparatus. The first distance A can be the same as or different from the second distance B.

In the present embodiment, in the first bending direction S1, the distance between the first opening 100 and the second opening 400 that are adjacent is greater than twice the first distance A, that is, greater than 2A. In the second bending direction S2, the distance between the first opening 100 and the second opening 400 that are adjacent is greater than twice the second distance B, that is, greater than 2B. In this way, a staggered configuration of the openings can be achieved, so that a larger area can be hollowed out to form openings to enhance the bending effect of the support member, at the same time, the solid having sufficient support portion can also be retained to ensure that the support member can play a good role in supporting.

In some specific embodiments, in the first bending direction S1, the third distance G between the first opening 100 and the second opening 400 that are adjacent can be twice the first distance A (that is, 2A), three times the first distance A (that is, 3A), or four times the first distance A (that is, 4A), and so on, which can be set according to the actual situations. Similarly, in some specific embodiments, in the second bending direction S2, the fourth distance H between the first opening 100 and the second opening 400 that are adjacent can be twice the second distance B (that is, 2B), three times the second distance B (that is, 3B), or four times the second distance B (that is, 4B), and so on, which can also be set according to the actual situations.

In the present embodiment, a plurality of first openings 100 are arranged along the first bending direction S1 and the second bending direction S2. Each first opening 100 has a first region 110 and a second region 120, the midpoint of the first region 110 and the midpoint of the second region 120 are the same. In the first region 110, the first width D is less than the first length C. In the second region 120, the second width F is less than the second length E, enabling the display apparatus to bend along both the first bending direction S1 and the second bending direction S2 to achieve the bidirectional bending purposes. The openings on the support member can be classified based on their arrangement into the first openings 100 and the second openings 400. In the first bending direction S1, the distance between adjacent first openings 100 is the first distance A, and the third distance G between the first opening 100 and the second opening 400 that are adjacent in the first bending direction S1 is greater than twice the first distance A. In the second bending direction S2, the distance between adjacent first openings is the second distance B, and the fourth distance H between the first opening 100 and the second opening 400 that are adjacent in the second bending direction S2 is greater than twice the second distance B. Thus, the first openings 100 can be reasonably distributed to ensure that sufficient solid are reserved among the openings for support, while good bending effects can also be achieved. This effectively avoids the need to completely hollow out the intermediate rigid metal or carbon fiber to ensure the realizability of bidirectional bending, avoids that poor support in the hollowed-out regions is lead to and avoids that a problem such as a collapsing feel in the front display module mold printing of the display apparatus and the touch is resulted in.

At the same time, there is no need for extra filling with bendable materials, such as foam, PI, or PET, thus that the gap needed between the filling material and the surrounding support member due to the effect of fitting precision and material processing accuracy may lead to the problem of generating the front ring mold printing of the display apparatus is avoided. Thus, while the support effectiveness of the support member can be ensured, the problem of touch feeling in other areas may not exist.

In the description of this specification, it should be understood that the terms “center”, “longitudinal”, “lateral”, “length”, “width”, “thickness”, “up”, “down”, “front”, “back”, “left”, “right”, “vertical”, “horizontal”, “top”, “bottom”, “inner”, “outer”, “clockwise”, “counterclockwise”, “axial”, “radial”, “circumferential”, and other directional or positional relationships are based on the orientations or positional relationships shown in the accompanying drawings. These terms are merely for the sake of convenience in describing the present application and simplifying the description, and do not indicate or imply that the devices or components referred to must have a specific orientation or be constructed and operated in a specific orientation. Therefore, they should not be understood as limitations on the present application.

Furthermore, the terms “first” and “second” are used solely for descriptive purposes and should not be interpreted as indicating or implying relative importance or suggesting the quantity of technical features indicated. Thus, features limited as “first” or “second” may explicitly or implicitly include one or more such features. In the description of the present application, the term “plurality” means two or more, unless otherwise specifically defined.

In the present application, unless otherwise expressly stated and defined, the terms “install”, “connected”, “link”, “fixed”, and similar terms should be understood in a broad sense. For example, they can refer to fixed connections, removable connections, or integral formations; they can be mechanical connections or electrical connections, or even communication connections. They can involve direct connections or indirect connections through intermediaries, and they may refer to communication between elements or interactions between two elements. For a person skilled in the art, the specific meanings of these terms in the present application can be understood according to the specific conditions.

In the present application, unless otherwise expressly stated and defined, the expression of a first feature being “on”, “above”, or “over” a second feature can include direct contact between the first feature and the second feature, as well as cases where the first feature and the second feature are not in direct contact but are contacted through additional features between them. Moreover, when a first feature is described as being “above”, “over”, or “on top of” a second feature, it includes the cases where the first feature is directly above or obliquely above the second feature, or merely indicates that the horizontal height of the first feature is greater than the horizontal height of the second feature. When a first feature is described as being “below”, “under”, or “beneath” a second feature, it includes cases where the first feature is directly below or obliquely below the second feature, or merely indicates that the horizontal height of the first feature is less than the horizontal height of the second feature.

The above disclosure provides many different embodiments or examples for implementing the various structures of the present application. For the sake of simplifying the disclosure, components and arrangements of specific examples have been described. Of course, these are merely exemplarily and are not intended to limit this disclosure. Additionally, reference numbers and/or letters may be repeated in different examples in the present application, and this repetition is for the purposes of simplification and clarity; itself does not indicate any relationship between the various embodiments and/or arrangements being discussed.

The above is merely a specific embodiment of the present application, but the scope of protection of the present application is not limited to this. A person skilled in the art can easily conceive of various modifications or alternatives within the technical scope disclosed herein, and these should be covered within the protection scope of the present application. Therefore, the protection scope of the present application shall be subject to the scope defined by the claims.

1. A support member, comprising:
a plurality of first openings arranged in an array;
a plurality of second openings arranged in an array;
wherein in a first bending direction, a minimum distance between adjacent first openings is a first distance, and in a second bending direction, a minimum distance between adjacent first openings is a second distance;
in the first bending direction, a third distance between the first opening and the second opening that are adjacent is greater than twice the first distance, and in the second bending direction, a fourth distance between the first opening and the second opening that are adjacent is greater than twice the second distance; and
both the first opening and the second opening have a first region and a second region; for each of the first opening and the second opening, a midpoint of the first region and a midpoint of the second region are the same, a first width of the first region in the second bending direction is less than a first length of the first region in the first bending direction, and a second width of the second region in the first bending direction is less than a second length of the second region in the second bending direction.

2. The support member according to claim 1, wherein a value of the first length ranges from twice the first distance to 10 times the first distance.

3. The support member according to claim 1, wherein a value of the second length ranges from twice the second distance to 10 times the second distance.

4. The support member according to claim 1, wherein the second length is greater than the first width, and a value of the first width is obtained by subtracting a designated distance from the first distance, wherein the designated distance is less than the first distance.

5. The support member according to claim 4, wherein a value of the designated distance is taken between one-third of the first distance and four-fifths of the first distance.

6. The support member according to claim 1, wherein in the second bending direction, there is a first designated solid between the first opening and the second opening, and a line width of the first designated solid ranges from twice the second distance to 10 times the second distance; and
the support member further comprises at least one first half-etched groove, and each of the at least one first half-etched groove is arranged on the first designated solid along the second bending direction.

7. The support member according to claim 6, wherein a value of an etching depth of the each of the at least one first half-etched groove is taken between one-half of a thickness of the first designated solid and four-fifths of the thickness of the first designated solid.

8. The support member according to claim 1, wherein in the first bending direction, there is a second designated solid between the first opening and the second opening, and a line width of the second designated solid ranges from twice the first distance to 10 times the first distance; and
the support member further comprises at least one second half-etched groove, and each of the at least one second half-etched groove is arranged on the second designated solid along the second bending direction.

9. The support member according to claim 8, wherein a value of an etching depth of the each of the at least one second half-etched groove is taken between one-half of a thickness of the second designated solid and four-fifths of the thickness of the second designated solid.

10. The support member according to claim 1, wherein the first width is the first distance, the first length is 3 times the first distance, and the second length is 3 times the second distance; and
in the first bending direction, the third distance is 3 times the first distance, and in the second bending direction, the fourth distance is 3 times the second distance.

11. The support member according to claim 1, wherein the plurality of the first openings are arranged at equal intervals along the first bending direction and the second bending direction on the support member.

12. The support member according to claim 1, wherein the plurality of second openings are arranged at equal intervals along the first bending direction and the second bending direction on the support member.

13. The support member according to claim 1, wherein the first region extends along the first bending direction, and the first region is a rectangular through hole arranged along the first bending direction or an elongated through hole arranged along the first bending direction; and
the second region extends along the second bending direction, and the second region is a rectangular through hole arranged along the second bending direction or an elongated through hole arranged along the second bending direction.

14. The support member according to claim 1, wherein the first opening and the second opening are arranged in a staggered manner.

15. The support member according to claim 14, wherein an intermediate region of four first openings arranged in an array is configured with one second opening, and centers of the four first openings are connected to form a first rectangle, and a center of the second opening is positioned at a center of the first rectangle; and
an intermediate region of the four second openings arranged in an array is configured with one first opening, and centers of the four second openings are connected to form a second rectangle, and a center of the first opening is positioned at a center of the second rectangle.

16. The support member according to claim 1, wherein at both sides of the first opening and the second opening along the first bending direction, there are further a plurality of third openings arranged in an array, a length of the third opening along the first bending direction is greater than a width of the third opening along the second bending direction.

17. The support member according to claim 16, wherein a size of the third opening is the same as a size of the first region and a structure of the third opening is the same as the structure of the first region, and the third opening is parallel to the first region.

18. The support member according to claim 1, wherein a translation center of the first opening is a position obtained by translating a center of the first opening along the first bending direction to align with a center of the second opening in the second bending direction; and
a distance between the translation center of the first opening and the center of the first opening is the third distance, and a distance between the translation center of the first opening and the center of the second opening is the fourth distance.

19. A display apparatus, comprising the support member claim 1.

20. The support member according to claim 1, wherein the third distance refers to a distance, in the first bending direction, between a side edge of the second region of the first opening and a corresponding side edge of the second region of the second opening that is adjacent to the first opening; and the fourth distance refers to a distance, in the second bending direction, between a side edge of the first region of the first opening and a corresponding side edge of the first region of the second opening that is adjacent to the first opening.
